(19) United States
(12) Patent Application Publication
(10) Pub. No.: US 2003/0151904 A1
(43) Pub. Date: Aug. 14, 2003

(54) Decoration for providing luminescence and music

(76) Inventors: Jen-Fu Chen, Feng Yuan City (TW); Chih-Shen Chen, Taichung (TW)

Correspondence Address: Alan D. Kamrath, Rider, Bennett, Egan & Arundel, LLP, Suite 2000, 333 South Seventh Street, Minneapolis, MN, 55402, US

(21) Appl. No.: 10/073,380

(22) Filed: Feb. 11, 2002

(51) Int. Cl. G09G 3/10; H05K 1/18

(52) U.S. Cl. 361/761

(57) ABSTRACT

A decorative device includes a decorative laminate for providing luminescence and a driving element for powering and controlling the decorative laminate to provide various ways of luminescence. The decorative laminate includes a first electrode layer, a second electrode layer, a light-emitting layer sandwiched between the electrode layers, a decorative layer covering the first electrode layer, and a protective layer attached to the second electrode layer. The decorative laminate includes a plug connected with a number of wires extended therefrom. The driving element includes a socket for engagement with the plug. The driving element includes a power control unit for providing various voltages to the decorative laminate, a logical control unit for transforming physical conditions into signals, and a central control unit. The central control unit receives the signals from the logical control unit in order to instruct the power control unit to provide various voltages to the decorative laminate. Thus, the decorative laminate provides luminescence in various ways. The decorative device includes a speaker driven by the driving element to provide sound. The driving element includes a musical integrated circuit to record various melodies for the speaker.

### BACKGROUND OF INVENTION

1. Field of Invention

The present invention is related to decoration and, more particularly, to a decorative device for providing luminescence and music.

2. Related Prior Art

As human nature, people do not only use things for practical purposes but also things for decorative purposes. This is particularly true in a modern and rich society. To satisfy such human nature, people have devised a lot of decorations among which illuminative decorations may be most common.

FIG. 7 shows a conventional illuminative decorative device 30 including a panel 32 on which a decorative pattern 34 is formed. A light-transmitting line 36 is shaped in conformity with the contour of the decorative pattern 34. A cap-shaped lens 38 is connected with an extension of the light transmitting line 36. A supporting plate 40 defines in a first face a groove 42 corresponding to the light-transmitting line 36 and an aperture 44, and includes on a second face a casing 46. A circuit board 48 is connected with an LED 50. The light-transmitting line 36 is received in the groove 42 and the cap-shaped lens 38 is inserted through the aperture 44. The panel 32 is attached to the supporting plate 40 so that the contour of the decorative pattern 34 overlaps the light-transmitting line 36. The circuit board 48 is received in the casing 46 so that the LED 50 is received in the cap-shaped lens 38. Thus, light emitted from the LED 50 can be transmitted along the light-transmitting line 36 in order to highlight the contour of the decorative pattern 34. A cover 52 is used to seal the circuit board 48 and the LED 50 in the casing 46. Although providing decoration, this conventional decorative device is not satisfactory in several points. Firstly, it is thick due to the use of the LED 50. Secondly, it is rigid and fragile and can be easily broken when dropped from a height. Thirdly, it cannot make any sound to get people's attention.

The present invention is therefore intended to obviate or at least alleviate the drawbacks encountered in using conventional decorative device.

### SUMMARY OF INVENTION

It is the primary objective of the present invention to provide a decorative device that is thin and flexible and provides music.

To achieve the above-mentioned and other objectives, the present invention provides a decorative device including a decorative laminate for providing luminescence and a driving element for powering and controlling the decorative laminate to provide various ways of luminescence.

The decorative laminate includes a first electrode layer, a second electrode layer, a light-emitting layer sandwiched between the electrode layers, a decorative layer covering the first electrode layer, and a protective layer attached to the second electrode layer.

The decorative laminate includes a plug connected with a number of wires extended therefrom. The driving element includes a socket for engagement with the plug.

The driving element includes a power control unit for providing various voltages to the decorative laminate, a logical control unit for transforming physical conditions into signals, and a central control unit. The central control unit receives the signals from the logical control unit in order to instruct the power control unit to provide various voltages to the decorative laminate. Thus, the decorative laminate provides luminescence in various ways.

The decorative device includes a speaker driven by means of the driving element to provide sound. The driving element includes a musical integrated circuit to record various melodies for the speaker.

### BRIEF DESCRIPTION OF DRAWINGS

FIG. 1 is a perspective view of a decorative device according to the present invention;

FIG. 2 is a side view of the decorative device shown in FIG. 1;

FIG. 3 is a block diagram of a circuit used in the decorative device of the present invention;

FIG. 4 is a front view of the decorative device according to the present invention, showing a first sort of luminescence provided by means of the decorative device;

FIG. 5 is a view similar to FIG. 4, but showing a second sort of luminescence provided by means of the decorative device;

FIG. 6 is a view similar to FIGS. 4 and 5, but showing a decorative device according to a second embodiment of the present invention; and

FIG. 7 is an exploded view of a decorative device according to prior art.

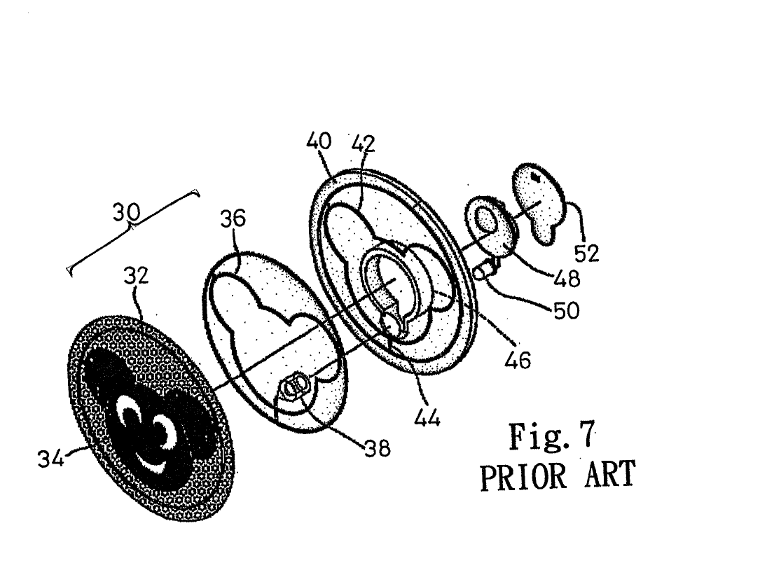

### DETAILED DESCRIPTION OF PREFERRED EMBODIMENTS

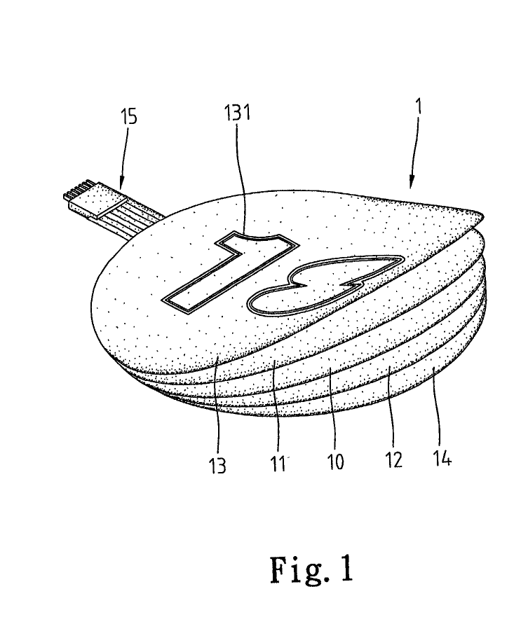

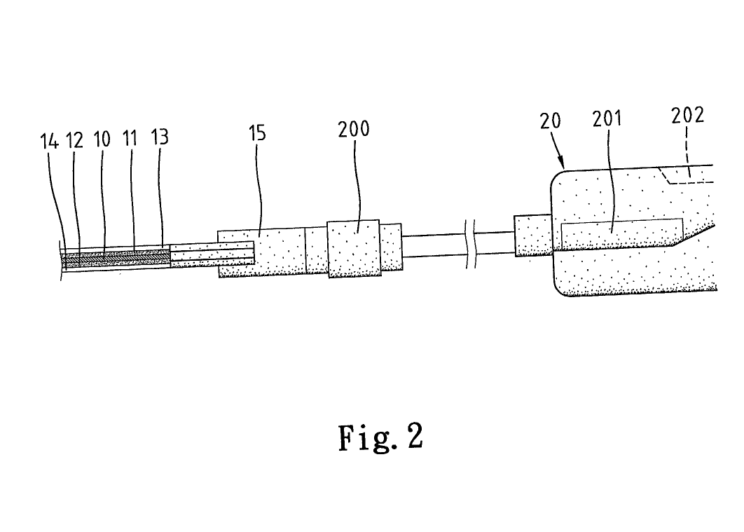

Referring to FIGS. 1 and 2, a decorative device according to a first embodiment of the present invention includes a decorative laminate 1, a speaker 202 and a driving box 20.

Referring to FIG. 1, the decorative laminate 1 includes a light-emitting layer 10, an upper electrode layer 11, a lower electrode layer 12, a decorative layer 13, and a protective layer 14. The light-emitting layer 10 is sandwiched between the electrode layers 11 and 12. The upper electrode layer 11 is covered with the decorative layer 13 on which a pattern 131 is formed. A protective layer 14 is attached to the lower electrode layer 12. A plug 15 is connected with a number of wires (not numbered) extended from the electrode layers 11 and 12.

Referring to FIG. 2, the plug 15 is inserted in a socket 200 of a driving box 20. The socket 200 is connected with a circuit board 201 received in the driving box 20. Thus, the decorative laminate 1 can be powered and controlled by means of the circuit board 201. The speaker 202 is installed in the driving box 20 and connected with the circuit board 201 so that the former is powered and controlled by means of the latter.

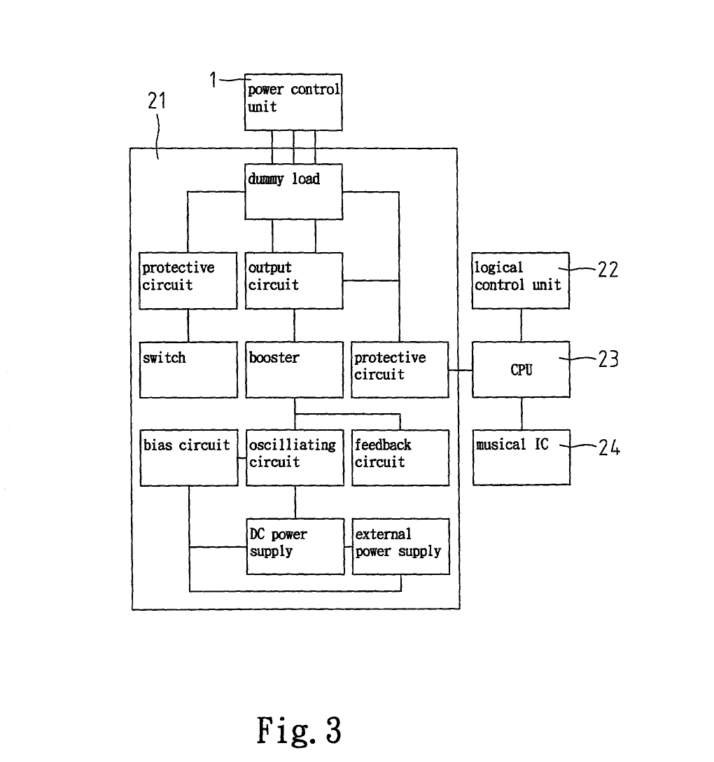

Referring to FIG. 3, on the circuit board 201, there are a power control unit 21, a logical control unit 22, a CPU 23, and a musical IC 24. The power control unit 21, the logical control unit 22 and the musical IC 24 are all connected with the CPU 23.

The power control unit 21 is used to control the power for driving the decorative laminate 1 to provide luminescence and for driving the speaker 202 to provide music. Thus, the decorative device of the present invention provides both video and audio signals to get people's attention.

The logical control unit 22 is used to transform physical conditions into signals. These signals are sent from the logical control unit 22 to the CPU 23 for calculation. Then, the CPU 23 instructs the power control unit 21 to control the power provided to the decorative laminate 1 so that the decorative laminate 1 can provide luminescence in various ways. Furthermore, the CPU 23 instructs the musical IC 24 that records a number of melodies or songs to provide the speaker 202 with various melodies or songs.

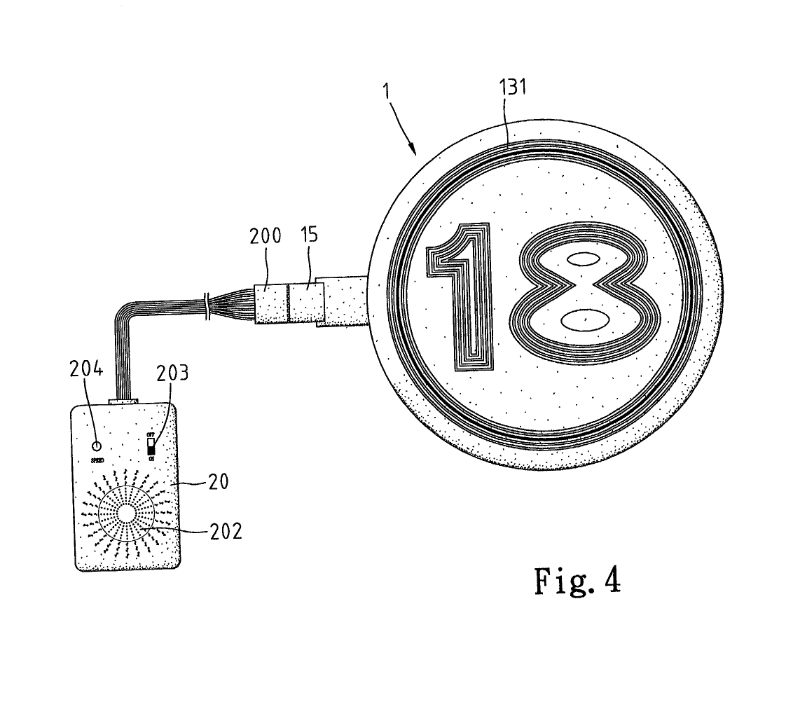

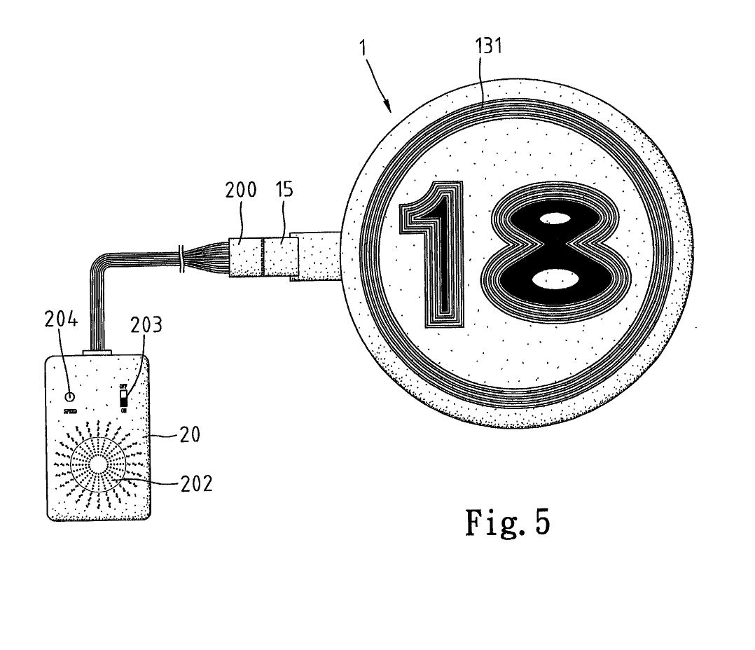

Referring to FIGS. 4 and 5, the driving box 20 includes a switch 203 and a knob 204 both connected with the circuit board 201. With the switch 203 turned to ON, the knob 204 can be rotated so as to drive the decorative device to provide luminescence as shown in FIG. 4 or FIG. 5. Similar, depending on various positions of the knob 204, various melodies or songs may be provided from the musical IC 24 to the speaker 202. Thus, different melodies or songs may go with different ways of luminescence.

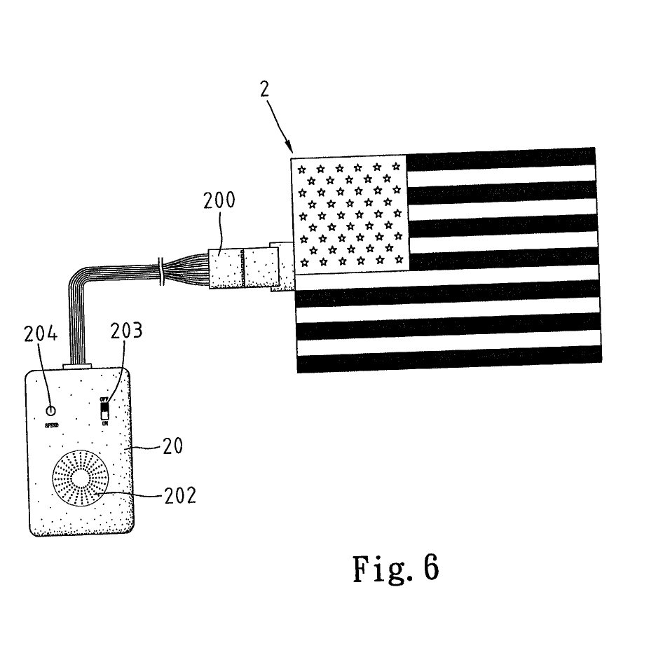

Referring to FIG. 6, according to a second embodiment of the present invention, a decorative device consists of a decorative laminate 2 and a driving box 20. The decorative laminate 2 is identical to the decorative laminate 1 except for including another pattern. Therefore, the second embodiment will not be described in further detail.

The present invention includes several advantages over the prior art. Firstly, the decorative device of the present invention is flexible and cannot be broken easily. Secondly, the decorative device of the present invention provides music in addition to luminescence. Third, the decorative device of the present invention provides various combinations of luminescence with music.

A number of embodiments of the present invention have been described in detail for purposes of illustration. Those skilled in the art can derive a lot of variations from these embodiments after a study of this patent specification. Therefore, these embodiments shall by no means limit the scope of the present invention. The scope of the present invention can only be defined in the following claims attached to and taken as a portion of this patent specification.

1. A decorative device including a decorative laminate (1; 2) for providing luminescence and a driving element (20) for powering and controlling the decorative laminate (1; 2) to provide various ways of luminescence.

2. The decorative device as set forth in claim 1 wherein the decorative laminate (1; 2) includes:
a first electrode layer (11);
a second electrode layer (12);
a light-emitting layer (10) sandwiched between the electrode layers (11; 12);
a decorative layer (13) covering the first electrode layer (11); and
a protective layer (14) attached to the second electrode layer (12).

3. The decorative device as set forth in claim 2 wherein the decorative laminate (1; 2) includes a plug (15) connected with a number of wires extended therefrom.

4. The decorative device as set forth in claim 3 wherein the driving element (20) includes a socket (200) for engagement with the plug (15).

5. The decorative device as set forth in claim 1 wherein the driving element (20) includes:
a power control unit (21) for providing various voltages to the decorative laminate (1; 2);
a logical control unit (22) for transforming physical conditions into signals; and
a central control unit (23) for receiving the signals from the logical control unit so as to instruct the power control unit to provide various voltages to the decorative laminate (1; 2) so that the decorative laminate (1; 2) provides luminescence in various ways.

6. The decorative device as set forth in claim 1 including a speaker (202) driven by means of the driving element (20) to provide sound.

7. The decorative device as set forth in claim 6 wherein the driving element (20) includes a musical integrated circuit (24) to record various melodies for the speaker (202).
